(19) United States
(12) Patent Application Publication
(10) Pub. No.: US 2005/0093559 A1
(43) Pub. Date: May 5, 2005

(54) Connection pin

(76) Inventors: Chikaomi Mori, Yamaga-shi (JP); Masanari Nakashima, Arao-shi (JP)

Correspondence Address: MEYERTONS, HOOD, KIVLIN, KOWERT & GOETZEL, P.C., P.O. BOX 398, AUSTIN, TX, 78767-0398, US

(21) Appl. No.: 10/951,279

(22) Filed: Sep. 27, 2004

(30) Foreign Application Priority Data
Sep. 26, 2003 (JP) JP2003-336400

(51) Int. Cl. G01R 31/02

(52) U.S. Cl. 324/761

(57) ABSTRACT

It is an object of the present invention to provide a connection pin for a probe card which measures electrical characteristics of a semiconductor device such as a LSI ship. The connection pin for the probe card which tests the semiconductor device has a U-shaped or V-shaped spring part manufactured by etching or pressing of metal.

### BACKGROUND OF THE INVENTION

1. Field of the Invention

The present invention relates to a connection pin for electrically connecting a plurality of substrates which constitute a probe card for measuring electrical characteristics of a semiconductor device such as an LSI chip.

2. Description of the Background Art

There are a lateral type called cantilever type and a vertical type called perpendicular type in a probe card which measures electrical characteristics of a semiconductor device such as a LSI chip. The lateral type of probe card has an aspect which is not suitable for measuring many chips at the same time, which is required under the circumstances in which large-scale integration of the LSI chip is implemented and a tester is multiplexed, so that it is less used nowadays. Meanwhile, since the vertical type of probe card can use many probes and provides a high degree of freedom for a probe arrangement and it is suitable for measuring many chips at the same time, it is mainly used at present.

The vertical type of probe card comprises a main substrate comprising electrodes connected to electrodes of a measuring device, a space transformer comprising electrodes connected to electrodes of a tested object, and a sub-substrate provided between the main substrate and the space transformer, and a connection pin is used to electrically connecting them.

When the semiconductor device such as the LSI chip is tested, it is required that a plurality of chips are measured at the same time. Recently, there is a demand for a probe card having high stability in electrical contact, a high performance and high reliability even when the number of electrodes of the probe card used in the test is further increased.

As the connection pin for electrically connecting the substrates, as shown in FIG. 5, Japanese Patent No. 2781881 discloses the connection pin which is soldered to a second substrate and elastically comes into contact with a through-hole in a first substrate. This type of connection pin has been mainly used conventionally. However, according to this type of connection pin, when a substrate constitution of the probe card is changed according to the kind of the semiconductor device to be tested, since the connection pin cannot be removed from the second substrate, the constitution which can correspond to the semiconductor device to be tested is limited. Furthermore, when a connection pin is bent or broken, since it is not possible only that connection pin is removed, the second substrate has to be entirely exchanged in that case.

Still further, since the plurality of connection pins are completely fixed to the second substrate, if each connection pin is slightly shifted in position, it is difficult for the connection pin to be inserted. Therefore, it is necessary to solder the connection pin one-by-one, keeping extremely high positioning precision at the time of manufacturing, so that it takes time to manufacture the substrate.

[Patent Document 1] Japanese Patent No. 2781881

### SUMMARY OF THE INVENTION

It is an object of the present invention to provide a connection pin which can be easily detached one-by-one and provides stable electrical connection even after repetitive use, in a probe card for testing a semiconductor device.

In order to solve the above problems, a connection pin according to the present invention detachably provides electrical connection between first and second substrates having through-holes and comprises a first contact part which comes in contact with the through-hole provided in the first substrate, a first support part which supports the first contact part, a stopper which abuts on the surfaces of the first and second substrates, a second contact part which comes in contact with the through-hole provided in the second substrate and a second support part which supports the second contact part, in which the first and second contact parts have spring properties and elastically come into contact with side walls of the through-holes provided in the first and second substrates.

In addition, in order to solve the above problems, according to the connection pin of the present invention, there are provided a plurality of first and/or second contact parts.

Thus, according to the present invention, the connection pin detachably provides electrical connection between the first and second substrates having the through-holes, and comprises the first contact part which comes in contact with the through-hole provided in the first substrate, the first support part which supports the first contact part, the stopper which abuts on the surfaces of the first and second substrates, the second contact part which comes in contact with the through-hole provided in the second substrate, and the second support part which supports the second contact part, in which the first and second contact parts have spring properties and elastically come into contact with the side walls of the through-holes provided in the first and second substrates. As a result, it is easily detachable one-by-one and provides stable electrical connection even after repetitive use.

In addition, according to the connection pin of the present invention, since there are provided the plurality of first and/or second contact parts, its contact area is increased and further stable electrical connection is provided.

### BRIEF DESCRIPTION OF THE DRAWINGS

FIG. 1 is a partially schematic view showing a connection state of a connection pin according to an embodiment of the present invention;

FIG. 2 is an enlarged view showing a connection pin configuration according to the embodiment of the present invention;

FIG. 3 is an enlarged view showing another connection pin configuration according to the embodiment of the present invention;

FIG. 4 is an enlarged view showing still another connection pin configuration according to the embodiment of the present invention; and

FIG. 5 is a schematic view showing a connection state of a conventional connection pin.

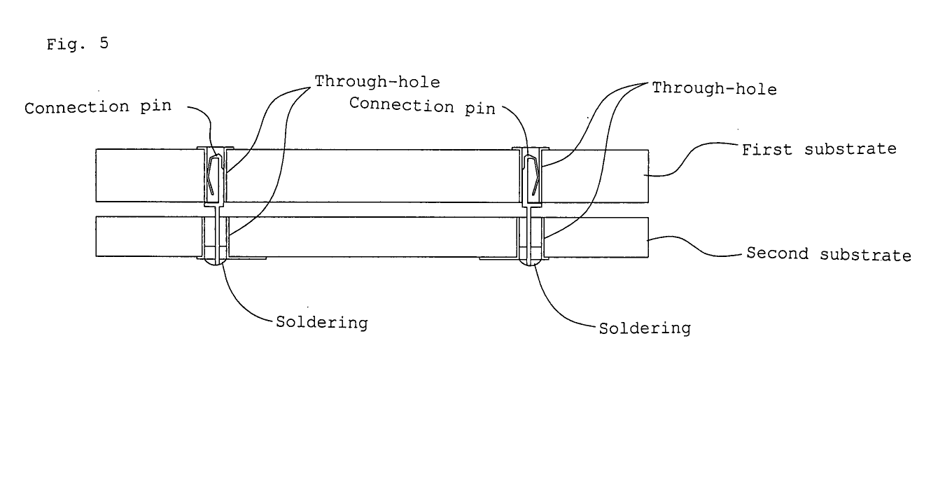

### DESCRIPTION OF THE PREFERRED EMBODIMENTS

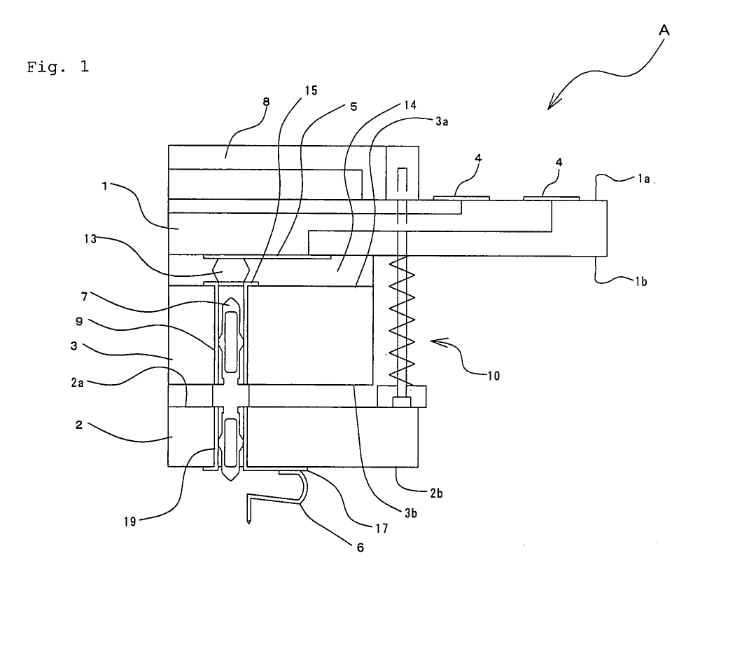

A probe card A, as apart of it is shown in FIG. 1, comprises a main substrate 1 having first connection electrodes 4 which come in contact with a measuring device for testing such as a tester (not shown), a sub-substrate 3 having a plurality of through-holes 9 electrically connected to the first connection electrode 4, a space transformer 2 having a plurality of through-holes 19 electrically connecting a one main surface 2a to the other main surface 2b and comprising a plurality of contactors 6 on the other main surface 2b, which come into contact with a semiconductor device (not shown) which is a tested object such as an IC chip or the like, a connection pin 7 which is detachably inserted to the through-hole 9 in the sub-substrate 3 and the through-hole 19 in the space transformer 2, and a holding jig 10 which detachably mounts the space transformer 2 on the main substrate 1.

As shown in FIG. 1, the main substrate 1 comprises the plurality of first connection electrodes 4 on the first main surface 1a, which are electrically connected to the measuring device for testing, and comprises a plurality of second connection electrodes 5 which are electrically connected to the sub-substrate 3 to be described below on the second main surface 1b. The second connection electrode 5 is electrically connected to the first connection electrode 4 by a wiring in the main substrate.

According to the main substrate 1, the first connection electrodes are arranged on the first main surface 1a so as to correspond to electrodes of the measuring device by transforming a narrow interval space between the adjacent second connection electrodes on the second main surface 1b to a wide interval space between the adjacent first connection electrodes on the first main surface 1a.

As shown in FIG. 1, the sub-substrate 3 comprises a first main surface 3a which is opposed to the second main surface 1b of the main substrate 1, and a second main surface 3b which is opposed to a first main surface 2a of the space transformer 2 to be described below. The plurality of through-holes 9 are provided between the first main surface 3a and the second main surface 3b.

The through-holes 9 having electrically conductive plated layers penetrate between the first main surface 3a and the second main surface 3b and they are electrically connected to a plurality of third connection electrodes 15 provided on the first main surface 3a.

The space in the sub-substrate 3 between the third connection electrode 15 of the sub-substrate 3 and the second connection electrode 5 of the main substrate 1 is fixed by soldering or a conductor 13 made of an electrically conductive resin or the like, and the part other than the conductor between the second main surface 1b of the main substrate 1 and the first main surface 3a of the sub-substrate 3 is filled with a resin material 14 for bonding the substrates. Thus, the sub-substrate 3 is integrally provided with the main substrate 1 while it is electrically connected to the main substrate 1.

As shown in FIG. 1, the space transformer 2 comprises the first main surface 2a which is opposed to the second main surface 3b of the sub-substrate 3 and the second main surface 2b comprising the plurality of contactors 6 which are to come into contact with the electrodes of the semiconductor device (not shown) provided at high density.

As shown in FIG. 1, in the space transformer 2, there are provided the through holes 19 which penetrate between the first main surface 2a and the second main surface 2b. The connection pin 7 is inserted into the through-hole 19. A plurality of fifth connection electrode 17 are provided on the second main surface 2b of the space transformer 2 and the contactors 6 are soldered to the fifth connection electrodes 17.

The adjacent contactors 6 on the space transformer 2 correspond to electrodes of the semiconductor device (not shown) arranged at narrow intervals.

The connection pin 7 detachably provided in the through-hole 19 of the space transformer 2 is detachably inserted into the through-hole 9 of the sub-substrate 3 and as shown in FIG. 1, it is elastically in contact with inner surfaces of the through-hole 9 having electrically conductive plated layer and the through-hole 19 so as to electrically connect them.

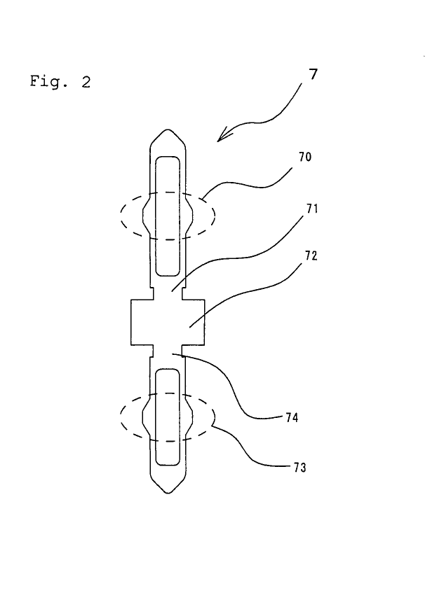

The connection pin 7 of the present invention is manufactured of a conductive material such as copper (Cu), nickel (Ni) or the like by etching, pressing or electroforming and preferably plated with gold (Au), tin (Sn) or the like. As shown in FIGS. 1 and 2, the connection pin 7 comprises a first contact part 70 which elastically comes in contact with the through-hole 9 of the sub-substrate 3, a first support part 71 which supports the first contact part, a stopper 72 which abuts on the surfaces of the substrates, a second contact part 73 which elastically comes in contact with the through-hole 19 of the space transformer 2, and a second support part 74 which supports the second contact part. In addition, its ends have U-shaped or V-shaped configurations in order to be able to be smoothly inserted into the through-hole.

According to the connection pin 7 of the present invention, when the first contact part 70 and the first support part 71 are inserted into the through-hole 9 of the sub-substrate 3, the first contact part 70 comes in contact with the inner wall of the through-hole having the conductive plated layer so that the through-hole 9 of the sub-substrate 3 and the connection pin 7 can be electrically connected as shown in FIG. 1 and FIG. 2. When the space transformer 2 is lowered, the first contact part and the first support part of the connection pin 7 can be withdrawn from the through-hole 9.

The first contact part 70 and the first support part 71 of the connection pin 7 are inserted into the through-hole 9 of the sub-substrate 3 such that the contact part elastically come into contact with the inner surface of the through-hole 9, and the second contact part 73 and the second support part 74 are inserted into the through-hole 19 provided in the space transformer 2 such that the contact part elastically comes into contact with the inner wall of the through-hole 19. Thus, the through-hole 19 of the space transformer 2 and the connection pin 7 are electrically connected, so that the through-hole 9 of the sub-substrate 3 and the through-hole 19 of the space transformer 2 are electrically connected. Of course, the space transformer 2 and the connection pin 7 can be easily separated.

In this case, when the space transformer 2 is separated from the sub-substrate 3, the member in which the connection pin 7 remains can be selected by providing a difference between spring pressure of the first contact part 70 of the connection pin 7 on the side of the sub-substrate 3 and spring pressure between the through-hole 19 provided in the space transformer 2 and the second contact part 73 of the connection pin 7. That is, if the spring pressure on the side of the sub-substrate 3 is higher than that on the side of the space transformer 2, when the space transformer 2 is separated, the connection pin 7 surely remains in the sub-substrate 3 (if the spring pressure on the side of the space transformer 2 is higher, the connection pin 7 remains in the space transformer 2).

FIG. 2 is an enlarged view showing the connection pin 7 according to the present invention described in FIG. 1. The connection pin 7 comprises the first contact part 70 which elastically comes in contact with the through-hole 9 of the sub-substrate 3, the first support part 71 which supports the first contact part, the stopper 72 which abuts on the surfaces of the substrates, the second contact part 73 which elastically comes in contact with the through-hole 19 of the space transformer 2, and the second support part 74 which supports the second contact part. The connection pin 7 is manufactured of a conductive material such as copper (Cu), nickel (Ni) or the like by etching, pressing or electroforming and preferably plated with gold (Au), tin (Sn) or the like.

Since the connection pin 7 shown in FIG. 2 according to the present invention has two contact points at one contact part 70, a contact area is doubled as compared with the conventional one, and since the first and second support parts 71 and 74 have closed configurations, a damage when the connection pin 7 is pulled out can be effectively prevented. In addition, since the connection pin 7 is symmetrical with respect to a center line of the through-hole, it can be automatically centered in the through-hole when it is inserted, which is applicable to a case of fine pitch in which the connection pins are closely arranged.

Although the configuration shown in FIG. 2 is manufactured by a processing method such as etching, pressing or electroforming only, since the processing method does not use a process for bending metal, there is no metal fatigue caused in the process. As a result, there is provided the connection pin 7 in which spring properties do not deteriorate even after it is repeatedly used, and durability is excellent.

According to the connection pin 7 shown in FIG. 2, the contact part and the support part can be changed in length or width, depending on a thickness of the substrate or a size of the through-hole to which the connection pin 7 is inserted. In addition, its configuration is not limited to the illustrated configuration. If the thickness of the substrates and the size of the through-holes are the same, the connection pin 7 can be symmetrical with respect to the stopper 72.

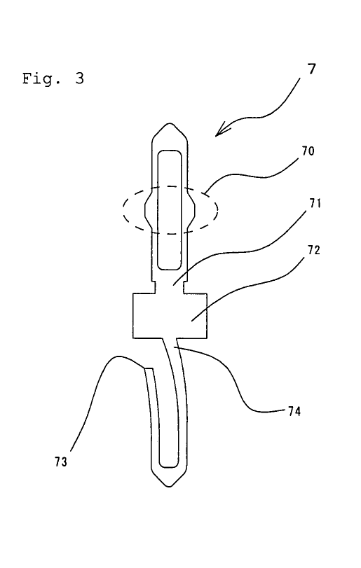

As shown in FIG. 3, one contact part may be in the shape of hook, so that it gets hung up in the pulling-out direction. As a result, the substrate in which the connection pin 7 remains can be surely determined.

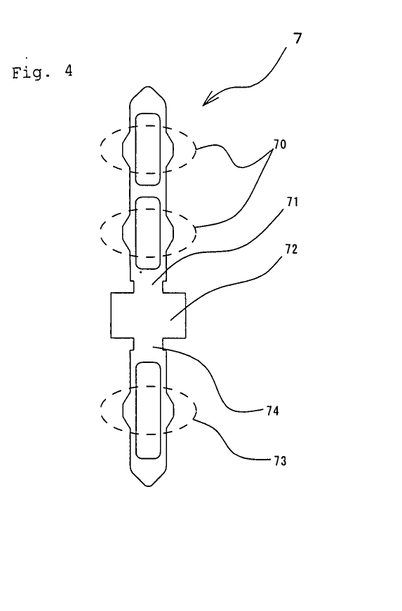

The connection pin 7 according to the present invention may have a constitution in which a plurality of first contact parts 70 are provided as shown in FIG. 4. That is, when the plurality of first contact parts 70 are provided, its contact area is doubled and electrical conduct characteristics are further improved. Alternatively, a plurality of second contact parts 73 may be provided, or the plurality of first and second contact parts may be provided on both sides. When the plurality of first contact parts or second contact parts are provided, since the contact pressure of respective contacts is the same but insertion/withdrawal force is doubled on either side, the substrate in which the connection pin remains is determined.

As can be clear from the above description, the connection pin electrically connects the first and second substrates having through-holes in which it is detachably inserted, and the connection pin comprises a first contact part which comes in contact with the through-hole of the first substrate, a first support part which supports the first contact part, a stopper which abuts on the surfaces of the first and second substrates, a second contact part which comes in contact with the through-hole in the second substrate, and a second support part which supports the second contact part. Since the first and second contact parts are constituted so as to have spring properties and elastically come into contact with side walls of the through-holes provided in the first and second substrates, the connection pin is detachable one-by-one and it can provide stable electrical connection even after repetitive use.

In addition, according to the connection pin of the present invention, since there may be provided the plurality of the first and/or the second contact parts, the contact area is multiplied and further stable electrical connection can be provided.

1. A connection pin detachably providing electrical connection between first and second substrates having through-holes, comprising:
a first contact part which comes in contact with the through-hole provided in the first substrate;
a first support part which supports the first contact part;
a stopper which abuts on the surfaces of the first and second substrates;
a second contact part which comes in contact with the through-hole provided in the second substrate; and
a second support part which supports the second contact part, wherein the first and second contact parts have spring properties and elastically come into contact with side walls of the through-holes provided in the first and second substrates.

2. The connection pin according to claim 1, wherein a plurality of first and/or second contact parts are provided.
